(19) United States
(12) Patent Application Publication
(10) Pub. No.: US 2009/0233461 A1
(43) Pub. Date: Sep. 17, 2009

(54) Method of Manufacturing a Printed Circuit Board

(76) Inventor: Joseph A. A. M. Tourne, Helmond (NL)

Correspondence Address: DUNLAP CODDING, P.C., PO BOX 16370, OKLAHOMA CITY, OK, 73113, US

(21) Appl. No.: 12/049,810

(22) Filed: Mar. 17, 2008

(51) Int. Cl. H01R 12/00; H05K 3/20

(52) U.S. Cl. 439/65; 29/831

(57) ABSTRACT

A method of making a circuit board comprising the steps of: (1) forming two or more metallized vias through at least a portion of a circuit board; and (2) forming an isolation opening between the two or more metallized vias, whereby at least a portion of the metallization is removed from at least one of the two or more vias

### CROSS REFERENCE TO RELATED APPLICATIONS

This application claims the benefit of Holland Patent Application No. NL 1033546, filed Mar. 16, 2007, which is hereby incorporated herein by reference in its entirety. This claim for priority is made through both the Paris Convention and the World Trade Organization (WTO), as Holland is a member country of both. This application also claims the benefit of U.S. Provisional Patent Application No. 60/919,263, filed Mar. 21, 2007, which is hereby incorporated herein by reference in its entirety.

### BACKGROUND

1. Field of the Invention

In general, the invention relates to the manufacture of printed circuit boards (PCBs). More particularly, but not by way of limitation, the invention relates to methods of manufacturing PCBs to encourage the mutual isolating of vias therein, as well as the PCBs constructed by such methods.

2. Brief Description of the Prior Art

PCB's for electrical connectors and connections, as well as packages of semi-conductors that may be placed on PCB's, often use substrates to provide support, rigidity, and the like. These substrates are often constructed with resin weaved or non-weaved fibre-structures. Such fibres may consist of glass fibres, organic fibres, or the like. Although such configurations have met with some success, a number of shortcomings still exist therein. For example, moisture, temperature extremes and variations, and electrical voltage extremes and variations can have negative effects on the substrate as well as on the print traces. Such negative effects may cause leakage currents or current leaks along the fibres, which in turn, may result in high-resistance connections between traces, pads, holes, and the like.

Such leakage currents or current leaks are generally caused by the flow of ions along one or more fibres. This phenomenon may be known in the art as a “Conductive Anodic Filament” (CAF) effect, and may effectively restrict the minimum distance between conductive elements on or in PCB's. This CAF-effect often occurs especially between pads and fully-metalized holes, also called vias. As will be appreciated by those skilled in the art, the CAF effect may have a significant impact on a PCB, which may consist of multiple layers, and may have multiple vias, traces or layers connected to one another on one or more levels of the PCB. With such PCB components, and especially with vias, it is desirable in many applications to place them as close to each other as possible. However, the proximity of such placement may effectively be limited by the CAF effect.

In the past, improvements on or reduction of the CAF effect have been attempted by coating fibres with a non-conductive coating before the fibres are processed in or into the PCB-substrate material. However, such coatings have not resulted in significant improvements.

The miniaturization of PCBs may also be limited by a number of other problems as well. For example, the drilling of smaller holes meets with difficulties such as, for example, drill wander, decreased accuracy due to the increase of hole depth in proportion to the hole diameter, as well as various other difficulties. Additionally, the dimensions of semi-conductor packages or components may also be limited. For example, differences in expansion coefficient between the semi-conductor packages or components and a PCB may lead to mechanical stress or tension between the semi-conductor packages or components and the PCB. Such stresses may weaken joints and connections such as soldered connections and may lead to the failure of such connections.

Alternative technologies, such as laser drilled blind holes, have their own shortcomings. For example, with laser drilled blind holes, generally not enough layers can be drilled to the total number of traces needed to unravel the complex “Area Array Package”. In what may be known in the art as “sequential construction”, several layers can be built up, but this method is highly complex and may be cost prohibitive due to the high number of process-steps.

As such, there is a perpetual need for further, and more effective, techniques for miniaturizing PCBs, such as by reducing the distance between semi-conductor components, and by placing more conductive traces between vias.

### SUMMARY

One purpose of the invention is to enable the construction of vias closer to one other by reducing or counteracting the CAF-effect, such that PCBs may be made smaller overall or such that more components such as vias and the like may be placed on PCBs. In one embodiment of the invention, a method of manufacturing a PCB preferably includes the steps of: providing a pattern of conductive traces on a PCB; providing two or more metalized vias in a PCB, connecting each of the two vias by way of one or more conductive traces; and providing an isolation opening between at least two of the two or more vias, wherein the isolation opening is contiguous part of the at least two vias, and at least one turned part of the metallization is removed.

By removing circuit board substrate material between the at least two proximal or closely-positioned vias, as well as by removing part of the facing via metallization of each of at least two vias, the distance between the conductive portions of the at least two vias is increased and the substrate fibres therebetween are removed over which a CAF failure could occur, such that the isolation in general is improved. As a result, vias may be placed closer together than comparable vias may be placed in PCBs where the portion of substrate therebetween is not removed. Additionally, imperfections in the circuit board material between the holes are eliminated by the removal of such material.

As a result of decreasing the distance between vias, the density of the components may be increase, e.g., components may be placed closer together, more traces may be routed between rows of via-holes, or trace width may be increased. For example, the trace widths can be increased for power and ground layers. By way of another example, where via holes are placed under the component connections, the distance between rows of component connections may be decreased, and components with smaller dimensions may be used. In this way, the complexity of a circuit board may be reduced by reducing the number of layers needed for making connections. Alternatively, more complex circuits may be built in the same area.

In one preferred embodiment, the size of the isolation opening is larger then the diameter of the vias. For example, where the isolation opening and the vias are round, the diameter of the isolation opening is preferably larger than the diameter of at least one of, and more preferably both of, the vias.

In another embodiment, the isolation opening between the two metalized vias is preferably filled with a non-conductive material. For example, the performance or effectiveness of the isolating properties of the isolation opening may be improved by filling at least a portion of, and more preferably all of, the isolation hole with a material having better isolating properties than the circuit board substrate material itself.

In yet another embodiment, the non-conductive material preferably has a dielectric constant that is different from that of the circuit board substrate material. For example, the dielectric constant of the non-conductive material may be higher than or lower than the dielectric constant of the substrate. This difference in dielectric constant may be used to control or tune the impedance between the vias, for example, to cause such impedance to be approximately equal to, more preferably substantially equal to, and most preferably exactly equal to the impedance between the impedance of the traces. For example, the non-conductive material may be provided with a dielectric constant such that the impedance therethrough is approximately, substantially, or exactly equal to a coupled pair of traces.

In yet another embodiment, the metallized vias are preferably filled with a reinforcing material prior the creation of the isolation opening between the vias. In this way, the reinforcing material preferably helps to ensure the structural integrity of the vias during and after the creation of the isolation opening, as well as preferably reduces the likelihood and or number of burrs created by drilling or otherwise creating the isolation opening between the vias.

In yet another embodiment, the reinforcing material of via holes is preferably a conductive material. In this way, when a pad or the like is created on top of the via, a better mechanical and electrical connection is thereby achieved.

In a further embodiment, after filling one or both of the vias and the isolation holes, the surface of the circuit board and the non-conductive or reinforcing fill material is preferably levelled to provide a substantially flat surface. In this way, the surface of the circuit board is preferably levelled to enable the creation or addition of structures on the surface of the circuit board. In a related embodiment, a pad or the like is created on top of one or more vias.

In yet another embodiment, one or more traces may be connected to the vias to form a transmission line with a characteristic impedance. As described above, the dielectric constant of the non-conductive material in the isolation opening is preferably selected such that the impedance between vias matches the impedance of the traces, for example, to result in improved, substantially-undistorted transmission of the signal, and thereby improve the performance of the circuit board, especially in high-frequency applications.

In the manner and according to the various methods described herein, a variety of circuit boards may be obtained having the improved characteristics described herein.

### BRIEF DESCRIPTION OF THE DRAWINGS

FIG. 1 is a cross-sectional view of a circuit board having two metalized vias constructed in accordance with the present invention.

FIG. 2 is a top view of a portion of the circuit board having two metalized vias in a laterally offset configuration constructed in accordance with the present invention.

FIG. 3 is a top view of a portion of a circuit board having two metalized vias in a diagonally offset configuration constructed in accordance with the present invention.

FIG. 4a is a top view of a portion of a circuit board having two metalized vias and an isolation opening therebetween constructed in accordance with the present invention.

FIG. 4b is a top view of a portion of a circuit board having three metalized vias and an isolation opening constructed in accordance with the present invention.

FIG. 5 is a perspective view of a construction with two vias and an isolation hole (opening) constructed in accordance with the present invention.

FIG. 6 is a cross-sectional view of the construction of FIG. 5 taken along the lines I-II and II-III of FIG. 5.

FIG. 7a is a perspective view of a plurality of constructions each with two via holes and an isolation hole and a plurality of traces constructed in accordance with the present invention.

FIG. 7b is a perspective view of a plurality of vias and a plurality of traces constructed in accordance with prior art.

FIG. 8a is a perspective view of a plurality of constructions with two vias and an isolation hole in combination with power and ground layers constructed in accordance with the present invention.

FIG. 8b is a perspective view of a plurality of via holes in combination with power and ground layers constructed in accordance with the prior art.

FIG. 9a is a top view of the various states of the circuit board in various process steps that may be used to construct a circuit board with two vias and an isolation hole in accordance with the present invention.

FIG. 9b is a cross-sectional view of the various states of the circuit board of FIG. 9a taken along the lines V-VI, VII-VIII, IX-X, XI-XII, XIII-XIV, XV-XVI of FIG. 9a.

### DETAILED DESCRIPTION OF EXEMPLARY EMBODIMENTS

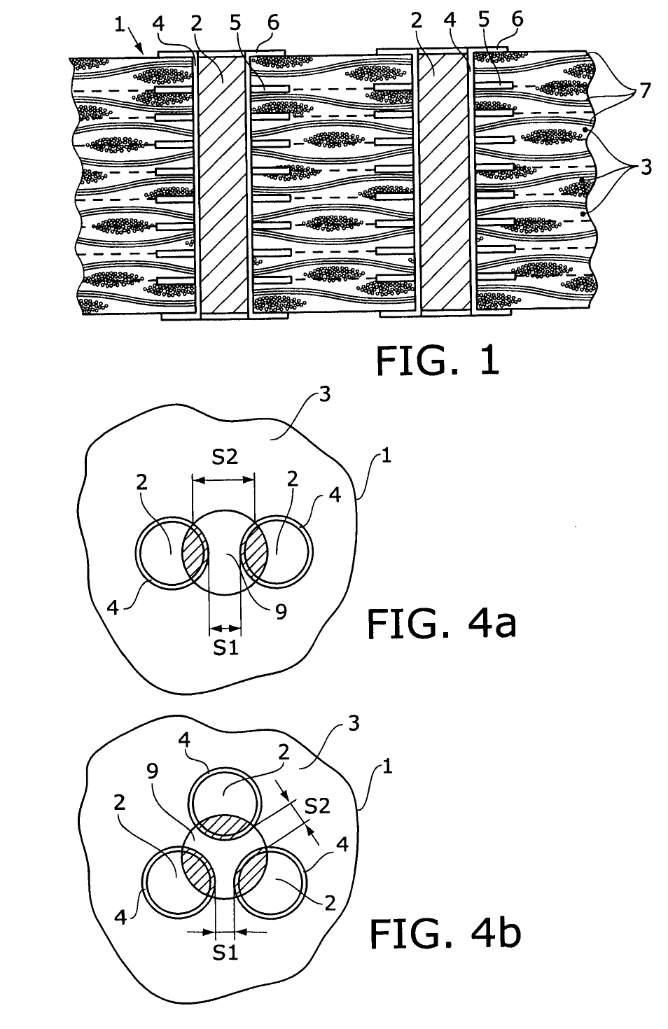

Referring now to the drawings, and more particularly to FIG. 1, shown therein and designated by the reference numeral 1 is an exemplary circuit board. The circuit board 1 is preferably constructed out of multiple layers of circuit board substrate material 3, each layer preferably consisting of fiber-reinforced resin 7. For example, the fiber-reinforced resin may be an epoxy resin with glass fibers wherein the fibers 7 are in a woven horizontal and/or orthogonal pattern and spread out in the circuit board substrate material 3.

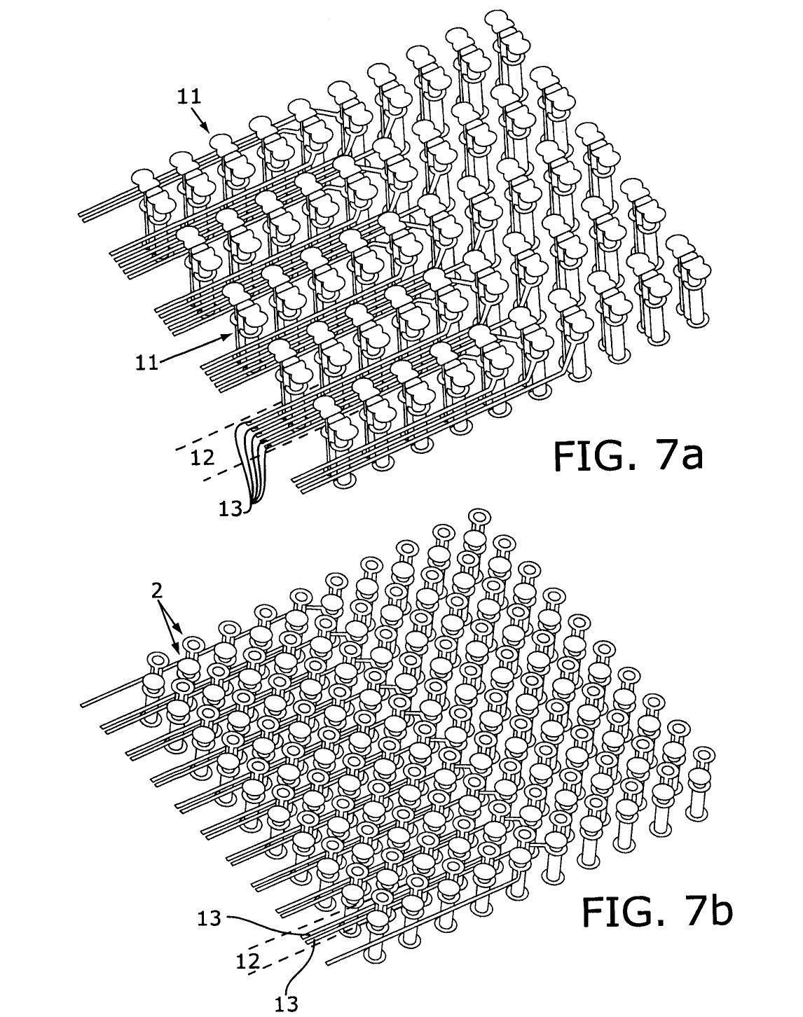

The vias 2 are preferably holes formed perpendicular to the circuit board 1 in the layers of the circuit board substrate material 3. A metal layer 4 is preferably applied to, or coats, the inside of the vias 2. The metal layer is also preferably connected to the pads 5, which may be disposed on the circuit board substrate material 3, as shown, such as for example connecting with the rest of the circuit board 1. (see, e.g., FIGS. 7a and 7b). Additionally, the vias 2 on the upper and lower sides of the circuit board 1 may connect to a pad (not shown) to be used for making electrical contact or to solder a component lead on.

As discussed above, one important factor for leakage currents is the fibers 7, which are used as reinforcement material in the circuit board 1. The smaller the distance between the vias 2, the more likely the CAF effect.

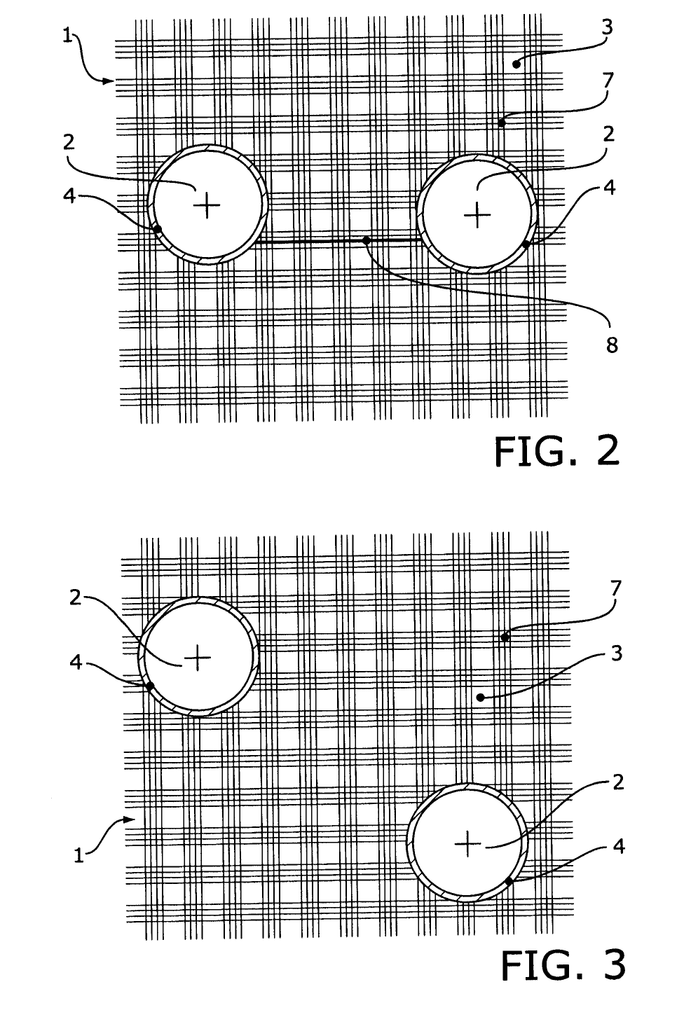

Vias 2, when placed in an orthogonal relationship as shown in FIG. 2, may be more sensitive or susceptible to the CAF effect. In this circumstance, as in others, the ion flow 8, which causes the CAF effect, generally follows individual fibers 7. One potential solution is to place vias 2 in diagonally-spaced relation to the orthogonal woven fiber structure shown in FIG. 3. However, this will increase the distance between vias 2, such that adjacent vias 2 preferably do not contact the same fiber 7. The disadvantage of this method is that it strongly reduces the design freedom and limits the ability to change or modify the absolute direction of woven fiber 7 reinforcements.

Referring now to FIG. 4a, shown therein is a top view of a portion of the circuit board 1 with two vias 2 having an isolation opening 9 therebetween in accordance with the present invention. As indicated by the hatched portions, a portion of the circuit board between the vias 2 is removed by the formation of the isolation opening 9. The vias 2 are preferably disposed in relatively close proximity to one another, with a distance s1 between the metallization rings 4 of the vias 2. By removing the circuit board substrate material 3, and thereby creating opening 9 and removing the hatched portions (FIG. 4a) of the vias 2, the effective distance between the metallization rings 4 of the vias 2 is increased to distance S2. In one embodiment, the isolation opening 9 may be left open or unfilled, i.e., filled with air. In other embodiments, the isolation opening may be filled with a first fill material 15 that preferably has non-conductive or less-conductive properties than the fiber-reinforced substrate material 3, or stated another way, that does not have the negative effects as that of the fiber reinforced substrate material 3. With the filling of the isolation opening 9, the via 2 opening may optionally be filled as well.

As shown in FIG. 4b, the present invention may also be applied to formations or constructions having more than two adjacent vias 2. As depicted in both FIGS. 4a and 4b, the isolation opening 9 is preferably a hole with a larger diameter than that of the vias 2.

By increasing the effective distance S2, the distance S1 between vias 2 can be decreased such that a greater number of vias 2 may be placed in a given area or region. This is particularly true where the isolation opening 9 is filled with a fill material 15 having non-conductive or otherwise preferably properties than the fiber reinforced substrate material 3 of the circuit board 1. The first fill material 15 used to fill the isolation opening 9 may be epoxy resins, such as for example epoxy resins modified for specific properties, e.g., to match the expansion coefficient of the circuit board substrate material 3. Such fill materials may be constructed of resin (epoxy or modified epoxy) materials and may be modified or mixed with materials such as ceramic to modify properties such as expansion coefficients. Examples of materials suitable for the first fill material 15 are known in the art as PHP900, PP2795, and THP100DXI.

In another embodiment of the present invention, the vias 2 may be filled with a second fill material 10 prior to the formation of the isolation opening 9, for example to reinforce the vias 2, to prevent the metallized rings 4 from generating burrs when forming the isolation opening 9, and the like. The second fill material 10 may be a conductive material, for example to create a conductive surface area to build a contact area 6 or pad 6. Examples of conductive materials suitable for use as the second fill material 10 for filling vias 2 are: copper- or silver-filled resins, such as for example the resin known in the art as CB100. Alternatively, the conductive material can be formed by fill plating the vias 2 with copper forming a solid copper/conductive column.

As depicted in the figures, one embodiment of the structure of the present invention includes two or more metalized holes or vias 2 with a preferably non-metallized isolation opening 9, disposed between the vias 2. In this way, paths formed by the fibers 7 between the vias 2, along which ion currents 8 may flow, are preferably eliminated by the isolation opening 9, thereby reducing and more preferably eliminating the CAF effect between the vias 2. In this way, there is preferably no path that can lead to electrical shorts or leakage currents.

In the prior art, a typical center-to-center distance between vias 2 may be 1.0 mm. With the present invention, the center-to-center distance between vias 2 may be reduced to a fraction of that previously utilized, such as for example 0.25 mm. With the present invention, the reduction in distance between vias 2 is primarily limited by mechanical and other considerations such as drill wander. For example, when drill wander is to large, the substrate material 3 may break away and/or the drill bit may break.

As shown, the creation of the isolation opening 9 may also remove a portion of the metallization of the via 2. This may also result in the conductivity of the vias 2 being correspondingly reduced. Similarly, the resistance of the vias 2 may vary in an inversely-proportional relationship with the conductivity. On average, the inventor has found that the average resistance of a full via 2 may be about 3 mOhm, depending on the diameter of the via 2, the thickness of the circuit board 1, and various other factors. When a portion of the via 2 is removed by the creation of the isolation hole 9, the inventor has further found that the resistance of the via 2 may increase to a range of approximately 4 to 5 mOhm, also depending on the diameter of the via 2, the thickness of the circuit board 1, and various other factors. This increase in resistance is relatively small, and in most applications, will likely have little or no negative impact on the performance of the circuit board 1, especially because the trace resistance may generally only be approximately a few hundred mOhm to several Ohms.

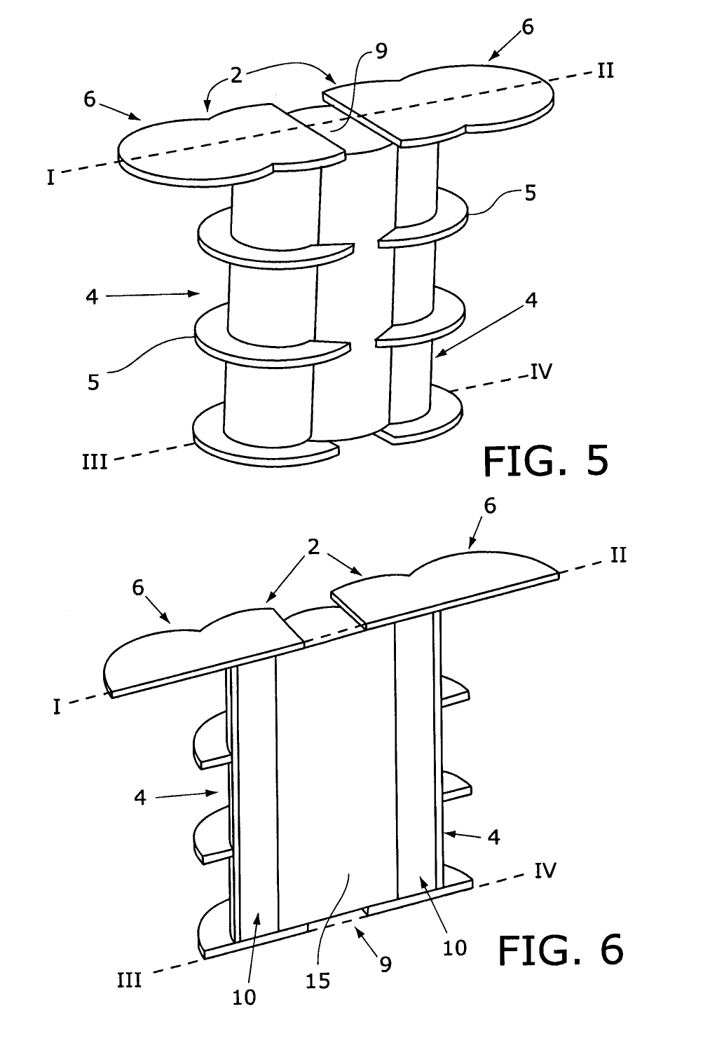

Referring now to FIG. 5, shown therein is a construction of two vias 2 with an isolation opening 9 therebetween in accordance with the present invention. This construction may be referred to herein as a three-hole construction 11. The three-hole construction 11 is shown in perspective, separate from the circuit board 1. The three-hole construction 11 preferably includes two vias 2, each covered with a pad 6. The pad 6 is preferably in physical and electrical communication with the metallization 4 of the vias 2. As described above, the isolation opening 9 may be filled with a non-conductive material or may be left open to form an air gap between the two vias 2.

Referring now to FIG. 6, shown therein is a cross-sectional view of the three-hole construction 11 of FIG. 5 taken along the lines I-II and III-IV. In the embodiment shown, the isolation opening 9 is filled with a first non-conductive material 15 and the vias 2 are filled with a second material 10, as described above. The three-hole construction 11, that preferably includes two or more vias 2 and an isolation opening 9, may be placed in the circuit board 1 under, for example, what may be known in the art as an Area Array Package, such as a BGA (Ball Grid Array).

Referring now to FIG. 7a, shown therein is a plurality of three-hole constructions 11 disposed in an exemplary BGA-type footprint, for example, with a pitch of 1.0 mm. As shown, the present invention preferably permits a wider channel 12 between the vias 2 that may, for example, be used for routing traces 13. In the channel 12 shown, a larger traces may preferably be routed than in a circuit board constructed in accordance with the prior art. The increase in the number of traces 13 may vary according to various factors, such as for example, the number and size of pads, the number and width of traces, the distance between traces and pads, and the like. By way of comparison, FIG. 7b depicts an exemplary prior art circuit board having 2 traces per channel 12, e.g., 1.0 mm pitch.

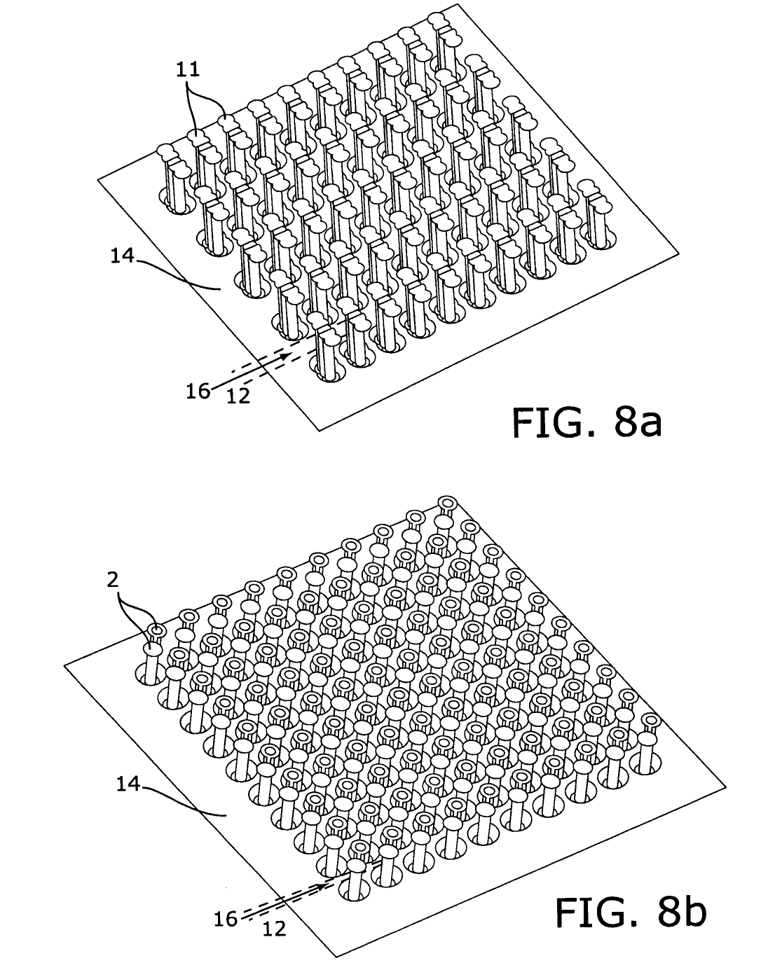

Referring now to FIG. 8a, shown therein is a plurality of three-hole constructions 11, in combination with a power and ground layer 14, and constructed in accordance with the present invention. Examples of benefits on the power and ground layer 14 that may be attained by the present invention include the following: a wider channel 12 may be formed between the three-hole constructions 11, a wider connection (conductive path) 16 may be formed on the power and ground layer 14, e.g., because there is preferably more room for copper. In this way, resistance may be decrease by increasing the width of connections. By way of comparison, FIG. 8b depicts a plurality of vias 2 in combination with a power and ground layer 14 constructed in accordance with the prior art.

With prior art component packages, a problem arises when the amount of copper used in connections 16 between vias is small. The relatively small size results in higher resistance and less current flows. Traces 13 running under or above the power and ground layer 14 may experience distortion in their impedance, especially at the narrow copper areas on power and ground layer 14. As a result, traces may lose energy due to reflection as the impedance on these narrow areas is different from the impedance in thicker are more solid areas of copper. The present invention 11 preferably permits relatively larger connections to be formed with less-pronounced narrowing than in the prior art, thereby resulting in a significant reduction of the negative effects described above.

By selecting a fill material with desirable characteristics, the properties (and especially the high-frequency properties) of vias 2 may be improved. For example, by selecting a specific dielectric constant, the impedance of combination of two adjacent vias 2 connected to traces 13 in a coupled transmission line may be matched to the impedance of the traces 13. In the preferred embodiment, the impedances are about equal. The characteristic impedance of the traces 13 including the vias 2 is preferably thereby more continuous and compatible, with fewer distortions and fewer unwanted reflections. As such, the present invention may be used to improve the performance of high performance circuit boards 1.

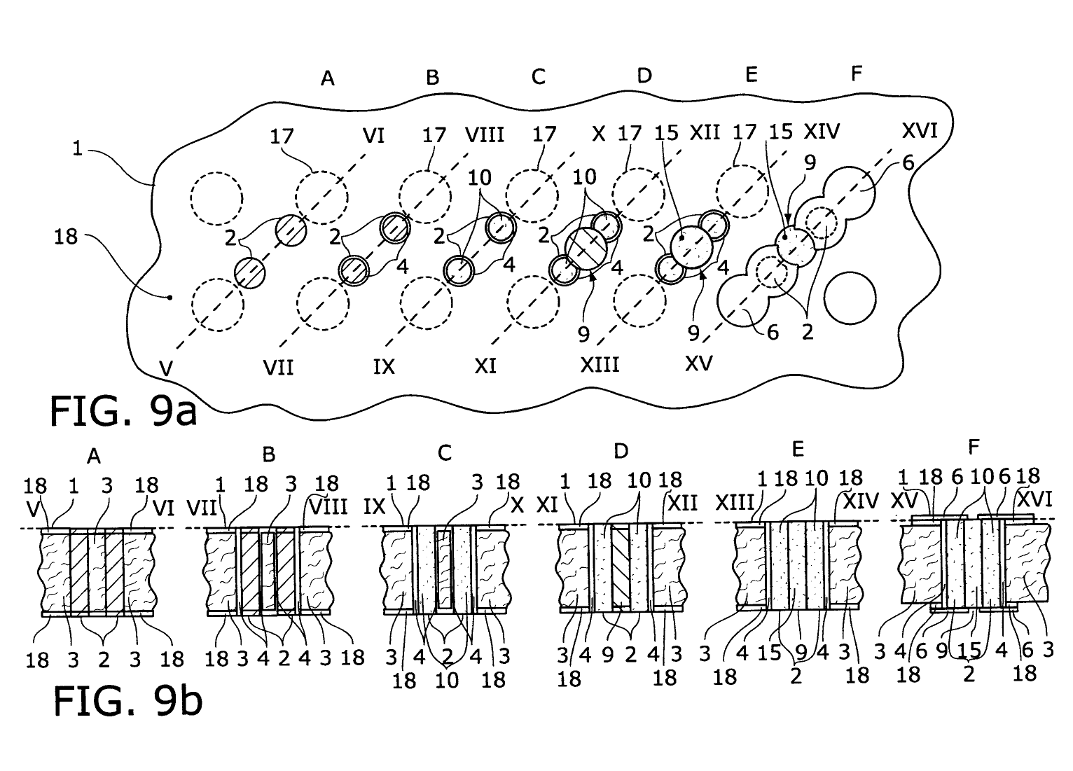

Referring now to FIGS. 9a and 9b, various top and cross-sectional views of an exemplary circuit board 1 are shown depicting various steps in one exemplary method of manufacturing a circuit board in accordance with the present invention.

FIG. 9a shows the top view of the circuit board 1 with multiple constructions 11, each having two vias 2 and an isolation opening 9, in the various process steps A through F of the exemplary method of manufacture. Process steps A to F are explained in more detail below. The exemplary circuit board 1 is shown with positions 17 that may be suitable for pads 6, as will be described in more detail below. For clarity, the example shown depicts the component pads 6 disposed on a pitch according to the prior art, for example with a pitch of 1 mm. The vias 2 are placed in a diagonal relationship, resulting in a space that may not allow traces 13 to be routed. However, in other embodiments, such as those depicted and/or described above, it is preferably to place the constructions 11 in a configuration that permits traces 13 to be routed therebetween.

FIG. 9b shows a plurality of cross-sectional views of the circuit board 1 of FIG. 9a in the process steps A to F, and taken along the lines V-VI, VII-VIII, IX-X, XI-XII, XIII-XIV and XV-XVI. Although the circuit board 1 is shown in FIG. 9b with only one layer of circuit board substrate material 3, other embodiments may be implemented with any suitable number of substrate layers, such as for example, two, three, and the like. The circuit board 1 depicted in FIGS. 9a and 9b includes conductive (copper) layers 18 on the top and bottom sides of the circuit board 1. Although these layers and structures spread out over the entire surface of circuit board 1, other embodiment may have any suitable number and/or configuration of such conductive layers 18.

The Process Steps A through F of the exemplary method of manufacture preferably include the following. The order in which the steps are presented is not intended to be limiting, and the steps may be reordered, omitted, or modified in any suitable manner permitting the construction and operation of various circuit boards and similar devices in accordance with the principles described herein.

Process Step A preferably includes the formation of two or more vias 2. The vias 2 may be formed by any suitable method, and may extend entirely through the circuit board 1 or only partially through the circuit board 1, as necessary or desired for specific applications.

Process Step B preferably includes plating or metallizing the vias 2. Similarly, the plating or metallizing may be completed by any suitable means. For example, this may be done using a conductive seed layer followed by an electrolytic plating process to build up a thicker conductive layer 4 of copper. The thickness of the layer is preferably such that it can absorb the mechanical stresses caused by differences in expansion coefficient between the substrate material 3 and the plating material in the via hole 2, so as to prevent the hole barrel from cracking.

Process Step C preferably includes filling the vias 2 with a fill material. This step is optional and may not be necessary or desired in certain embodiments. However, in the preferred embodiment, filling the vias 2 with filling material 10 preferably helps prevents burrs on the metallization as a result of drilling or other hole-formation processes to be described below. By filling the vias with a conductive material, or non-conductive material, pads may be formed on top of a filled via 2, such as for soldering a component lead to. The pitch between component leads may even be such that the pads may be used to form a component pad on.

Process Step D preferably includes formation of an isolation opening 9 in between the metallized vias 2. In this way, the circuit board material 3 is essentially replaced with air. Optionally, after the formation of the isolation opening 9, a cleaning step may be applied to remove debris from the opening. The formation of the isolation opening 9 may be done by any suitable means, such as for example, drilling, routing, laser ablation, or the like.

Process Step E preferably includes filling the isolation opening 9 with a non-conductive material 15. This step is optional and may not be necessary or desired in certain embodiments. The determination of whether to fill the isolation opening 9 may depend on various factors, for example, the space that is available for the formation of the pads 6 on the outer layers of the circuit board.

Process Step F preferably includes further processing of the circuit board 1, such as for example, by the addition of pads, traces, and the like through any suitable means know or developed in the art.

The examples in this description are exemplary of implementation of a three-hole construction 11, having with two or more vias 2 and an isolation opening 9, but may be further expanded with more than two vias 2 in combination with one or more isolation openings 9, whereby the one or more isolation openings 9 are each situated between two or more vias 2. The shape of the isolation opening is not limited to a round shape but may be any suitable shape such as oval, ellipse, square, rectangular, triangular, fanciful, or the like. Additionally, the principles described herein may be applied to vias that are drilled with laser ablation or other processes, for example, microvias. The principles described herein may also be applied to microvias, buried vias, blind hole or blind via structures, such as where a connection is made between one layer and the next but not necessarily extending between external surfaces of a circuit board. These structures may often be used in sequential build up circuit boards. Steps known in the prior art for the manufacture of circuit boards have been omitted for brevity, for example, the formation of traces and the like. Further, another advantage of bringing the vias closer together is that one via can be a signal via and an adjacent via can be a ground via and in this case the current return path is much better and the signal loss is smaller. With this technology the effect can be made bigger.

From the above description, it is clear that the present invention is well adapted to carry out the objects and to attain the advantages mentioned herein as well as those inherent in the invention. While presently preferred embodiments of the invention have been described for purposes of this disclosure, it will be understood that numerous changes may be made which will readily suggest themselves to those skilled in the art and which are accomplished within the spirit of the invention disclosed.

What is claimed is:

1. A method of making a circuit board comprising the steps of:
forming two or more metallized vias through at least a portion of a circuit board;
forming an isolation opening between the two or more metallized vias, whereby at least a portion of the metallization is removed from at least one of the two or more vias.

2. The method of claim 2, further comprising the step of:
filling at least one of the two or more vias with a first fill material prior to the step of forming the isolation opening.

3. The method of claim 2, wherein the first fill material is electrically conductive.

4. The method of claim 3, wherein the circuit board includes one or more traces in electrical communication with at least one of the two or more vias such that the one or more traces form a transmission line, and wherein the first fill material has a dialectric constant such that the characteristic impedance of the filled vias is about equal to the characteristic impedance of the one or more traces.

5. The method of claim 3, further comprising the step of:
levelling the first fill material such that the first fill material forms a substantially planar surface with an exterior surface of the circuit board.

6. The method of claim 3, further comprising the step of:
filling the isolation opening with a second fill material that is electrically non-conductive.

7. The method of claim 6, further comprising the step of:
levelling at least one of the first fill material and the second fill material such that the at least one of the first and second fill materials forms a substantially planar surface with an exterior surface of the circuit board.

8. The method of claim 7, further comprising the step of:
forming a pad on the exterior surface of the circuit board such that the pad is in electrical communication with at least one of the two or more vias.

9. The method of claim 1, whereby the diameter of the isolation opening is larger than the diameter of the at least one of the two or more vias.

10. The method of claim 9, further comprising the step of:
filling at least one of the two or more vias with a first fill material prior to the step of forming the isolation opening.

11. The method of claim 10, wherein the first fill material is electrically conductive.

12. The method of claim 11, wherein the circuit board includes one or more traces in electrical communication with at least one of the two or more vias such that the one or more traces form a transmission line, and wherein the first fill material has a dielectric constant such that the characteristic impedance of the filled vias is about equal to the characteristic impedance of the one or more traces.

13. The method of claim 11, further comprising the step of:
levelling the first fill material such that the first fill material forms a substantially planar surface with an exterior surface of the circuit board.

14. The method of claim 11, further comprising the step of:
filling the isolation opening with a second fill material that is electrically non-conductive.

15. The method of claim 14, further comprising the step of:
levelling at least one of the first fill material and the second fill material such that the at least one of the first and second fill materials forms a substantially planar surface with an exterior surface of the circuit board.

16. The method of claim 15, further comprising the step of:
forming a pad on the exterior surface of the circuit board such that the pad is in electrical communication with at least one of the two or more vias.

17. The method of claim 6, wherein the circuit board includes a substrate material and wherein the dielectric constant of the second fill material is higher than the dielectric constant of the substrate material.

18. The method of claim 17, further comprising the step of:
filling at least one of the two or more vias with a first fill material prior to the step of forming the isolation opening.

19. The method of claim 18, wherein the first fill material is electrically conductive.

20. The method of claim 19, wherein the circuit board includes one or more traces in electrical communication with at least one of the two or more vias such that the one or more traces form a transmission line, and wherein the first fill material has a dialectric constant such that the characteristic impedance of the filled vias is about equal to the characteristic impedance of the one or more traces.

21. The method of claim 19, further comprising the step of:
levelling the first fill material such that the first fill material forms a substantially planar surface with an exterior surface of the circuit board.

22. The method of claim 19, further comprising the step of:
filling the isolation opening with a first fill material that is electrically non-conductive.

23. The method of claim 22, further comprising the step of:
levelling at least one of the first fill material and the second fill material such that the at least one of the first and second fill materials forms a substantially planar surface with an exterior surface of the circuit board.

24. The method of claim 23, further comprising the step of:
forming a pad on the exterior surface of the circuit board such that the pad is in electrical communication with at least one of the two or more vias.

25. A circuit board, comprising:
a substrate material having two or more metallized vias formed at least partially through the substrate material, the substrate material further having an isolation opening formed between the two or more metallized vias such that at least a portion of the metallization is removed from at least one of the two or more vias.

26. The circuit board of claim 25, wherein at least one of the two or more vias is filled with a first fill material that is conductive.

27. The circuit board of claim 26, further comprising;
one or more traces in electrical communication with at least one of the two or more vias such that the one or more traces form a transmission line,
wherein the first fill material has a dialectric constant such that the characteristic impedance of the filled vias is about equal to the characteristic impedance of the one or more traces.

28. The circuit board of claim 26, wherein the isolation opening is filled with a second fill material that is electrically non-conductive.

29. The circuit board of claim 28, further comprising:
a pad disposed exterior to the substrate material such that the pad is in electrical communication with at least one of the two or more vias.

30. The circuit board of claim 1, wherein the diameter of the isolation opening is larger than the diameter of the at least one of the two or more vias.

31. The circuit board of claim 30, wherein at least one of the two or more vias is filled with a first fill material that is conductive.

32. The circuit board of claim 31, further comprising;
one or more traces in electrical communication with at least one of the two or more vias such that the one or more traces form a transmission line,
wherein the first fill material has a dielectric constant such that the characteristic impedance of the filled vias is about equal to the characteristic impedance of the one or more traces.

33. The circuit board of claim 31, wherein the isolation opening is filled with a second fill material that is electrically non-conductive.

34. The circuit board of claim 33, further comprising:
a pad disposed exterior to the substrate material such that the pad is in electrical communication with at least one of the two or more vias.

35. The circuit board of claim 28, wherein the dielectric constant of the second fill material is higher than the dielectric constant of the substrate material.

36. The circuit board of claim 35, wherein at least one of the two or more vias is filled with a first fill material that is conductive.

37. The circuit board of claim 36, further comprising;
one or more traces in electrical communication with at least one of the two or more vias such that the one or more traces form a transmission line,
wherein the first fill material has a dielectric constant such that the characteristic impedance of the filled vias is about equal to the characteristic impedance of the one or more traces.

38. The circuit board of claim 37, wherein the isolation opening is filled with a second fill material that is electrically non-conductive.

39. The circuit board of claim 38, further comprising:
a pad disposed exterior to the substrate material such that the pad is in electrical communication with at least one of the two or more vias.
